(19) United States
(12) Patent Application Publication
(10) Pub. No.: US 2006/0237647 A1
(43) Pub. Date: Oct. 26, 2006

(54) X-ray imaging device

(75) Inventors: Mitsushi Ikeda, Kanagawa-ken (JP); Akira Kinno, Kanagawa-ken (JP); Toshiyuki Oka, Kanagawa-ken (JP)

Correspondence Address: C. IRVIN MCCLELLAND;OBLON, SPIVAK, MCCLELLAND, MAIER & NEUSTADT, P.C., 1940 DUKE STREET, ALEXANDRIA, VA, 22314, US

(73) Assignee: Kabushiki Kaisha Toshiba, Tokyo (JP)

(21) Appl. No.: 11/414,483

(22) Filed: May 1, 2006

Related U.S. Application Data
(62) Division of application No. 09/986,896, filed on Nov. 13, 2001.

(30) Foreign Application Priority Data
Nov. 14, 2000 (JP) 2000-346565

(51) Int. Cl. G02F 1/01

(52) U.S. Cl. 250/330

(57) ABSTRACT

Signal output of an X-ray-electric conversion layer prevents instability of operation due to variation of a threshold voltage of TFT mounted to read a signal.

Pixel electrodes 17 are arranged in an array on the X-ray-electric conversion layer. Variation of the threshold voltage (Vₜₕ) is suppressed by applying in compensatory manner a voltage pulse for switch-off having a polarity opposite to an average polarity of a voltage for switch-on at operating period to the gate electrode of a field effect type TFT for pixel switching connected to each pixel electrode to read a signal.

### CROSS-REFERENCE TO RELATED APPLICATIONS

This application is based upon and claims the benefit of priority from the prior Japanese Patent Application No. 2000-346565, filed on Sep. 14, 2000; the entire contents of which are incorporated herein by reference.

### BACKGROUND

1. Field of the Invention

This invention relates to an X-ray imaging device.

2. Related Art

Various diagnostic appliances utilizing X-ray are widely put to use, and many of them are served for X-ray photography for diagnosis.

Recently, storing medical data of patients in a database has been progressing in order to treat them quickly and appropriately. When a patient consults a plurality of medical institutions, an appropriate medical treatment would be impossible without referring to the data stored in other medical institutions For example, if drugs prescribed by other medical institutions have not been notified, side reactions between the drugs and a newly prescribed drug may harmfully affect the patient's body, so that it is necessary to treat the patient taking the drugs prescribed by other medical institutions into account.

In reference to image data of X-ray photographs as well, obtaining the data already picked up by other medical institutions makes quick correspondence possible, and prevents similar X-ray irradiation from being carried out again. In medical X-ray diagnostic appliances, X-ray photographs were prepared with silver halide films so far. To digitize such images, after the photographed films have been developed, the developed images must be again scanned by a scanner or the like to get digital signals. Therefore these processes take much time.

Recently an II-TV (image intensifier television) accommodating a CCD (charge coupled device) camera of, for example, one-inch diameter has been used to prepare the database. However when the lung is to be photographed, indirect photographing for a large size of such as 40 cm by 40 cm is required. In consequence, its resolution, etc. are not sufficient and moreover the apparatus becomes large-scaled.

An X-ray imaging device utilizing an X-ray flat detector where MIS (metal insulator semiconductor) or MOS (metal oxide semiconductor) field effect transistor type a-Si TFTs (amorphous silicon thin film transistors) are arranged in an array as switching components has been proposed in, for example U.S. Pat. No. 4,689,487 to solve the problems in the above systems. FIG. 8 shows the X-ray flat detector.

In FIG. 8, a pixel 101 is composed of an a-Si TFT 102, a photoelectric conversion film 103, and a pixel capacitor (Cₛₜ) 104, and a plurality of the pixels 101 are arranged in a matrix array of several hundreds to several thousands in both vertical and horizontal sides. The photoelectric film 103 is supplied with a bias voltage through a power source 105. The a-Si TFT 102 is connected to a signal line 106 and a scanning line 107, and on/off operation is controlled by a scanning line drive circuit 108 comprising shift registers. A terminal end of the signal line 106 is connected to an amplifier 109 for detecting signals.

The photoelectric film 103 is formed of a layered film comprised of a fluorescent layer and a photoconductive layer. Light emanated from the fluorescent layer upon which X-ray impinges enters the photoconductive layer to generate electric charges.

When X-ray impinges upon the photoelectric film 103, a current flows therein, and an electric charge is stored in the pixel capacitor Cₛₜ 104. When all the TFTs 102 connected to one scanning line are turned on by driving each scanning line 107 through the scanning line drive circuit 108, the stored charge is transferred to the amplifier 109 side via the signal line 106. The amplifier 109 outputs a charge of every pixel, which is then converted into a dot sequence signal so as to be displayed on a display device such as a CRT (cathode ray tube). Because the amount of electric charge depends on the amount of the light entering the pixel, the output amplitude of the amplifier 109 varies.

In the system shown in FIG. 8, an output signal from the amplifier 109 is A/D-converted in order to produce directly a digital image. Furthermore, the image area in the figure has the same structure as a TFT switching array well known in liquid display devices, so that thin and large sized devices can easily be manufactured.

An amorphous silicon (a-Si) or a polycrystalline silicon (p-Si) that can be produced by low temperature process is employed as a semiconductor for a pixel driving TFT of the X-ray flat detector, and a SiN or a SiO₂ formed by plasma CVD (chemical vapour deposition) is principally used for the gate insulation film. Because this insulation film has inferior characteristics, as compared with a thermal-oxidized film formed on single crystal semiconductor that can be formed at a high temperature, reliability and life thereof become inferior. Precisely, there is a problem that if the gate electrode of the TFT is supplied with + (plus) bias voltage, Vₜₕ (threshold voltage) shifts toward + direction and then the current becomes difficult to flow. This is mainly caused by injection of carriers into the gate insulation film. The extent of the shift when the voltage between electrodes is positive is larger than that when the aforementioned voltage is negative.

It is necessary that intensity of the X-ray should be as weak as possible, and it is preferable that even a faint signal can be detected in order to get a large dynamic range. However, variation of the Vₜₕ makes the detection of the faint signal unstable, and consequently desirable wide range cannot be acquired.

Factors to determine the lower limit at which the faint signal can be utilized are an off-current of the protection diode and switching TFT, a signal shift due to a stray capacitance, noises of an operation amplifier, and so forth. The protection diode is connected to the pixel electrode to protect it from a break due to an over voltage of the switching TFT, in order to drain a leakage current from the pixel electrode when the voltage thereof exceeds the predetermined voltage. On the other hand, since the leakage current of the protection diode liberates the electric charge stored in the Cₛₜ connected to the pixel electrode, the least signal level that can be detected to a faint signal is forced to be limited. To prevent this phenomenon, reducing the leakage current is required. The protection diode is generally a TFT used as two terminals between the source electrode and the drain electrode, connecting the gate electrode of the TFT to the source electrode (drain electrode) thereof, so that it is necessary to make the characteristics of the TFTs employed uniform.

The present invention is to prevent the signal output of the X-ray-electric conversion surface from becoming unstable in operation caused by the variation on the threshold voltage of the TFT mounted to pick up the signal.

### BRIEF SUMMARY OF THE INVENTION

An aspect of the invention is an X-ray imaging device comprising:

an X-ray-electric conversion layer;

a plurality of pixel electrodes arranged in an array on one surface of the layer;

a field effect type thin film transistor connected to each pixel electrode for pixel switching, including source, drain and gate electrodes, either one of source and drain electrodes being connected to the pixel electrode, the other one being connected to a signal output line, and the gate electrode being connected to a scanning line; and

a gate drive circuit for switching the thin film transistor by applying a positive gate voltage pulse for switch-on to the gate electrode through the scanning line;

wherein the gate drive circuit in a switch-off period applies to the gate electrode a negative gate voltage for switch-off to prevent a threshold voltage from shifting generated by the positive gate voltage pulse for switch-on.

Moreover, compensation of Vₜₕ-shift can be performed by the absolute value of the negative gate voltage for switch-off of the thin film transistor for pixel switching being 30 to 200% of the absolute value of the positive gate voltage pulse for switch-on.

Another aspect of the invention is an X-ray imaging device comprising

an X-ray-electric conversion layer,

a common electrode arranged on one surface of the layer,

a plurality of pixel electrodes arranged in an array on the other surface of the conversion layer,

a field effect type thin film transistor connected to each pixel electrode for pixel switching, including source, drain and gate electrodes, either one of source and drain electrodes being connected to the pixel electrode, the other one being connected to a signal output line, and the gate electrode being connected to a scanning line, and

a field effect type thin film transistor for picking up a signal from the field effect type thin film transistor for pixel switching,

and the thin film transistor being driven by a driving gate voltage pulse,

wherein the X-ray imaging device comprises a correction control circuit for supplying a gate voltage with a polarity opposite to the gate voltage pulse to at least a part of the gate electrodes of the thin film transistors used for the X-ray imaging device, and the correction control circuit supplies the gate electrode with a gate voltage having a polarity of a direction that makes the mean value of the driver gate pulses at operating period of the imaging circuit be zero or reduced, during non-image reading period of the X-ray imaging device.

The device further comprises a noise corrective circuit comprising at least one step of field effect type TFT connected to the signal output line in parallel, and supplies a negative gate voltage for switch-off compensating a threshold voltage shift caused by the positive gate voltage pulse for switch-on to the field effect type TFT. In this case, it is preferable that the value of high voltage side of the gate voltage pulse for the field effect type TFT in the noise corrective circuit is reduced by the value of the threshold voltage.

The noise corrective circuit reduces noises through the driving pulse not affecting the signal output, by means of decreasing the potential of the signal output line connected to the field effect type TFT for pixel switching, which is turned on by the driving pulse applied to the scanning line, toward the direction opposite to the driving pulse so as to cancel an electric charge pulse generated by the pixel driving TFT. More precisely, a coupling electric charge that causes some noises generates through a parasitic capacitance between the scanning line and the signal output line. This electric charge is canceled by supplying for example a voltage pulse with a polarity opposite to the pixel voltage, to the gate electrode of the TFT in the noise corrective circuit. The variation of the Vₜₕ of the TFT becomes zero or decreases by means of pulse control using the corrective circuit control circuit.

It is preferable that the average supply voltage to the gate electrode of the thin film transistor in the noise corrective circuit is in the range between +30% and −30% of the average supply voltage to the pixel switching thin film transistor. To assure operation in the practical range, the average supply voltage to the gate electrode in the noise corrective circuit is preferably restricted in this range, as compared with the average supply voltage to the gate electrode of the pixel switching TFT.

The other aspect of the present invention is an X-ray imaging device comprising

an X-ray-electric conversion layer,

a plurality of pixel electrodes arranged in an array on one surface of the layer,

a field effect type thin film transistor for pixel switching, one of whose source electrode and drain electrode is connected to the pixel electrode, the other thereof being connected to a signal output line, and whose gate electrode being connected to a scanning line,

a protection diode comprising MIS thin film transistor connected to each pixel electrode and limiting the voltage of the pixel electrode to the value not to be in excess of the protection voltage,

a power source supplying a predetermined voltage to the common electrode,

a gate drive circuit switching the thin film transistor by supplying a driver gate voltage pulse to the gate electrode at operating period, and

a power circuit for the protection diode connected to the protection diode and supplying a limited voltage lower than the voltage of the power source,

wherein the power source for the protection diode supplies a voltage lower than the limited voltage at operating period to the protection diode at non-operating period.

When an X-ray sensitive layer such as a Se layer is used as the X-ray-electric conversion layer, there is a possibility that the switching TFT is damaged because the pixel electrode may suffer an excessive voltage due to especially a high voltage such as 10 kV across the layer applied for the top electrode. Therefore each pixel is connected to a protection diode. These protection diodes are comprised of connecting the drain electrode and the gate electrode to the pixel electrode, and formed on the same substrate together with the switching TFT, having the same structure of the gate insulation film as the switching TFT. The threshold voltage Vₜₕ shifts due to a deviation of the average polarity of the gate voltage (supplied voltage between the gate and the source). Here, the threshold voltage is defined as a value of the gate voltage at which source-drain current starts to flow when the gate voltage is increased from zero volts, and is used generally for the characteristics of the TFT. Square root of the current in the saturated region is usually linear to voltage, and the voltage at which the extension of this line crosses the voltage axis is the threshold voltages Shift of the Vₜₕ is moderated by varying the voltage of the diode power circuit at non-operating period.

The aforementioned non-operating period is preferably a blanking period.

Image scanning in the present invention may be the same as usual TV scanning system, and it is preferable that the flyback period of TV system is a non-operating period when X-ray radiation is stopped to decrease dosage of X-ray. Vₜₕ-shift can be moderated during the non-operating period.

### BRIEF DESCRIPTION OF THE DRAWINGS

FIG. 1 is a circuit diagram of an X-ray imaging device of an embodiment according to the present invention;

FIG. 2 is a plan view magnifying a part of a pixel portion of an embodiment according to the invention;

FIG. 3 is a cross section taken in line A-A in FIG. 2;

FIG. 4 is a diagram of log t-ΔVₜₕ curves explaining shift of threshold voltage Vₜₕ of a TFT;

FIG. 5 is a diagram showing forms of voltage pulses of an embodiment according to the invention;

FIG. 6 is a circuit diagram of another embodiment of the invention;

FIG. 7 is a diagram showing forms of voltage pulses of another embodiment according to the invention; and

FIG. 8 is a circuit diagram of a conventional device.

### DETAILED DESCRIPTION OF THE INVENTION

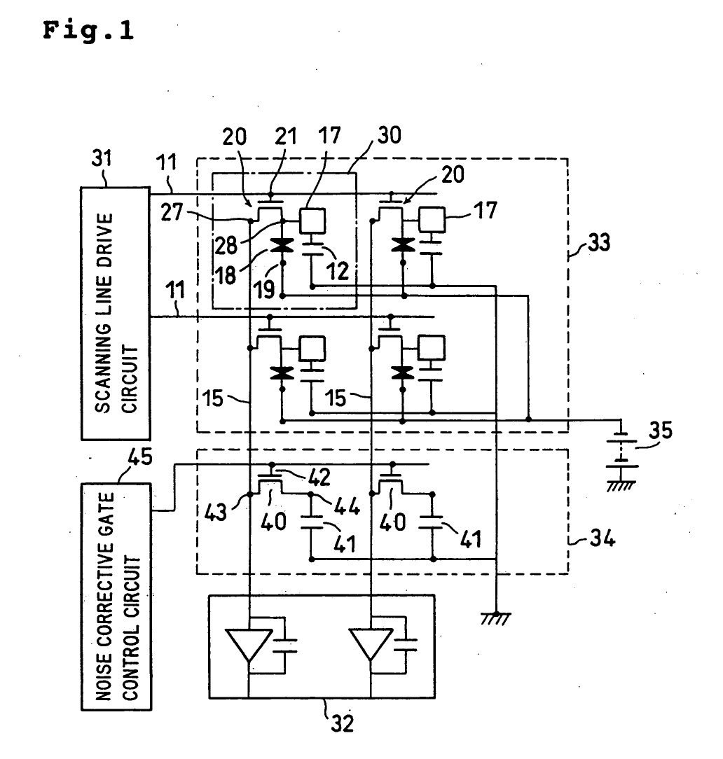

An embodiment of the present invention will be explained with referring to FIG. 1 to FIG. 5.

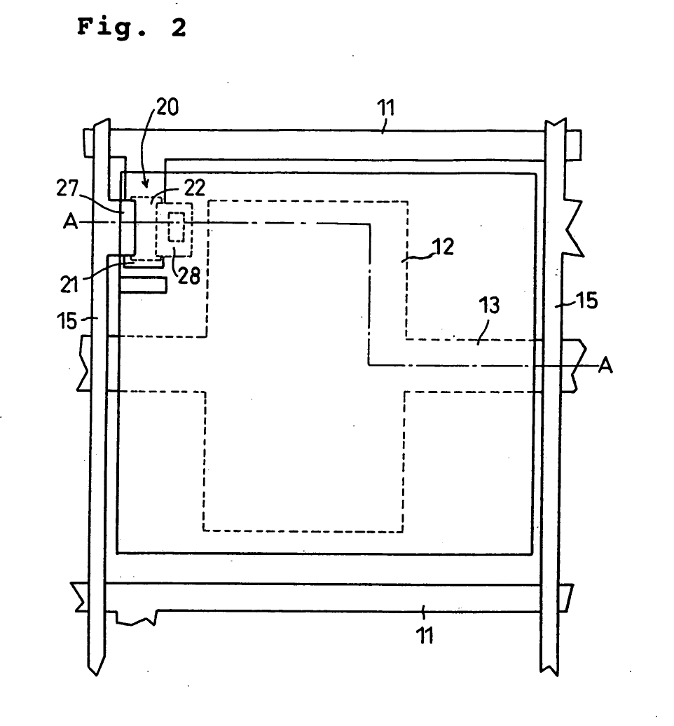

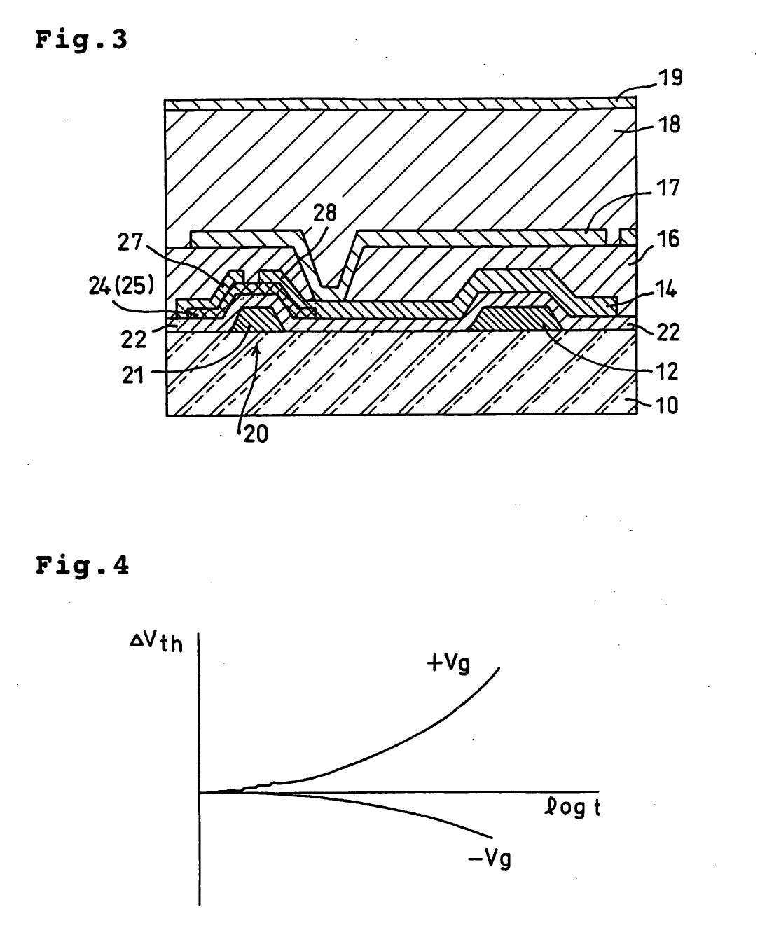

FIG. 2 and FIG. 3 are magnifications of a pixel of an X-ray-electric conversion device comprising a plurality of pixels arranged in a matrix array on a glass substrate. FIG. 2 is a plane figure, and FIG. 3 is a cross section taken in line A-A of FIG. 2.

All patterns of a gate electrode 21, a scanning line 11, a pixel capacitor Cₛₜ 12 and a Cₛₜ line 13 are simultaneously formed by etching process, after a metal film of 300 nm comprising a single layer of Ta, Al, Al alloy or MoW, or a double-layered structure of Ta—TaNₓ (Ta on TaNₓ) is deposited on a glass substrate 10. Next, SiOₓ of approximately 300 nm and SiNₓ of approximately 50 nm are deposited as an insulation film 22 by plasma CVD, and then undoped a-Si layer 24 of approximately 100 nm and SiNₓ of approximately 200 nm as a stopper (not shown) are deposited successively. After patterning the stopper self-aligned with the gate electrode using back side exposure, n⁺a-Si layer 25 of approximately 50 nm has been deposited. An island of a-Si is formed by etching the a-Si layer 24 and the n⁺a-Si layer 25 at the position where a TFT (field effect type thin film transistor) 20 is to be formed. A contact hole is formed by etching SiNₓ/SiOₓ of the contact portion of the electrodes outside the image area. Mo of approximately 50 nm and Al of approximately 350 nm are deposited thereon by sputtering in order to form a source electrode 27, a drain electrode 28, an auxiliary capacitance electrode 12, a signal output line 15 and other lines.

Then, SiNₓ of approximately 200 nm and photosensitive acrylic resin of approximately 1 to 5 micrometers preferably 3 micrometers are deposited successively to form a protecting film 16. After a-Si TFT 20 for pixel switching and a contact hole to the auxiliary capacitance electrode 12 have been formed, a pixel electrode 17 is formed with ITO film of approximately 100 nm in thickness. On the layer mentioned above, a Se layer 18 is formed to be the X-ray-electric conversion layer. The Se layer is comprised of an n type Se film for ohmic contact and blocking layer of 1 to 100 micrometers preferably approximately 30 micrometers, a Se film of 500 to 1000 micrometers preferably approximately 750 micrometers having a specific resistance of approximately 10¹² to 10¹⁶ ohm-cm, and a p type Se film of approximately 1 to 100 micrometers preferably approximately 30 micrometers for ohmic contact and blocking layer, filmed successively in the above order. On the Se layer, Al film of approximately 100 micrometers is formed as a common electrode 19. Finally the common electrode 19 is connected to a drive circuit. Consequently, an X-ray imaging device with a structure where pixel electrodes and n-channel type pixel switching TFTs are arranged in a matrix array on one surface of the X-ray-electric conversion layer is obtained.

FIG. 1 shows an equivalent circuit of a direct conversion type X-ray imaging device having the pixels explained by FIG. 2 and FIG. 3. In this circuit, the pixel 30 is comprised of the pixel switching a-Si TFT 20, the X-ray-electric conversion layer 18 and the pixel capacitor 12 (hereinafter referred to Cₛₜ), and the pixels 30 are arranged in a matrix array of several hundreds to several thousands in both vertical and horizontal sides (hereinafter called TFT array). The X-ray-electric conversion layer 18 is supplied with a negative bias voltage through a power source 35 connected to the common electrode 19. The pixel switching a-Si TFT 20 is connected to the signal output line 15 and the scanning line 11, and on/off operation thereof is controlled by a gate voltage pulse applied through the scanning line drive circuit 31. Namely, the TFT 20 is connected to one of the source electrode 27 and the drain electrode 28, and the other thereof is connected to the signal output line 15. Furthermore the gate electrode 21 is connected to the scanning line 11.

The terminal end of the signal output line 15 is connected to a signal detecting amplifier 32. A noise corrective circuit 34 is connected to the signal output line 15 in parallel as a part of outer peripheral circuit of a pixel array portion 33. The noise corrective circuit 34 is comprised of a series circuit of a corrective TFT 40 prepared by the same method as the pixel switching TFT 20 and a capacitor 41. A source electrode 43 is connected to the signal output line 15 in parallel. A drain electrode 44 of the corrective TFT is either grounded or connected to a bias power source having a potential near the ground via a capacitor 41. In the corrective circuit, the gate electrode 42 of the corrective TFT 40 is supplied with a negative voltage gate pulse through a pulse corrective gate control circuit 45. In consequence, the corrective circuit detects only charges accumulated by the pixel electrode and stored in a storage capacitor, after canceling of noise signals from the signal output. The noise signals are generated by switching of the gate electrode 21 of the pixel switching TFT 20, being coupled with a parasitic capacitance.

FIG. 4 shows the characteristics of an experiment where the TFT of the X-ray flat detector of this embodiment is kept to be at 80° C. and the gate electrode voltage (voltage between the gate electrode and the source electrode) is kept to be within ±25 volts. It is obvious that the threshold voltage Vₜₕ shifts to higher side as the time t passes. As the case may be, the shift greater than 10 volts may occur in 10⁴ seconds.

The shift of Vₜₕ is given as an equation (1):
dVₜₕ=A exp(−eEₐ/kT)(log t)^{β}(|V_{g}|)^{γ} (1)
where dVₜₕ is deviation value of Vₜₕ; t is effective applying time of gate voltage; V_{g} is gate voltage; and T is absolute temperature. A, Eₐ, β and γ are dependent upon the TFT. Usually, for positive V_{g}, A is 2 to 5 (3.5); Eₐ is 0.2 to 0.35 (0.25); β is 2 to 5 (3); and γ is 1 to 2.5 (1.7). Numbers in the parentheses are the typical values respectively.

For negative V_{g}, A is −5 to 50 (30); Eₐ is 0.25 to 0.5 (0.4); β is 2 to 5 (3); and γ is 1 to 3 (2). To correct the Vₜₕ exactly, correcting may be carried out in accordance with the characteristics of TFT. Because polarity of Vₜₕ-shift due to positive V_{g} and that due to negative V_{g} are opposite to each other, and then the average of V_{g} over the predetermined period becomes effective V_{g}, Vₜₕ-shift can be canceled by applying the V_{g} with opposite polarity.

Moreover, because the characteristics of Vₜₕ-shift are determined principally according to the type of the insulation film that contacts a-Si, though the characteristics depend on the type of gate insulation film, the shift is approximately equivalent to SiNₓ/SiOₓ multilayered film for SiNₓ gate insulation film, because SiNx is in contact with a-Si film. TFT-LCDs which is widely used are driven usually at the positive gate voltage of 20 to 30 V and the negative gate voltage of −2 to −5 V. On such bias condition, for a usual X-ray imaging device having a side of about 14 inches with pixel pitch of 150 micrometers and 2300 scanning lines, Vₜₕ varies approximately +8 V after driven for 50 thousand hours that is thought to be the necessary life, so that on-resistance cannot be sufficiently decreased even if TFT would be switched at a higher gate voltage, and consequently the device becomes useless. On the contrary, if the absolute value of −V_{g} pulse becomes the same as that of +V_{g}, the shift of Vₜₕ decreases by about 4 V, and then the on-resistance can sufficiently be reduced. To lengthen the life of the pixel transistor, the absolute value of the gate voltage of −V_{g} should be 30 to 200% of the absolute value of +V_{g}, preferably 40 to 120% in view of the ability of the driving power source system in order to be usable.

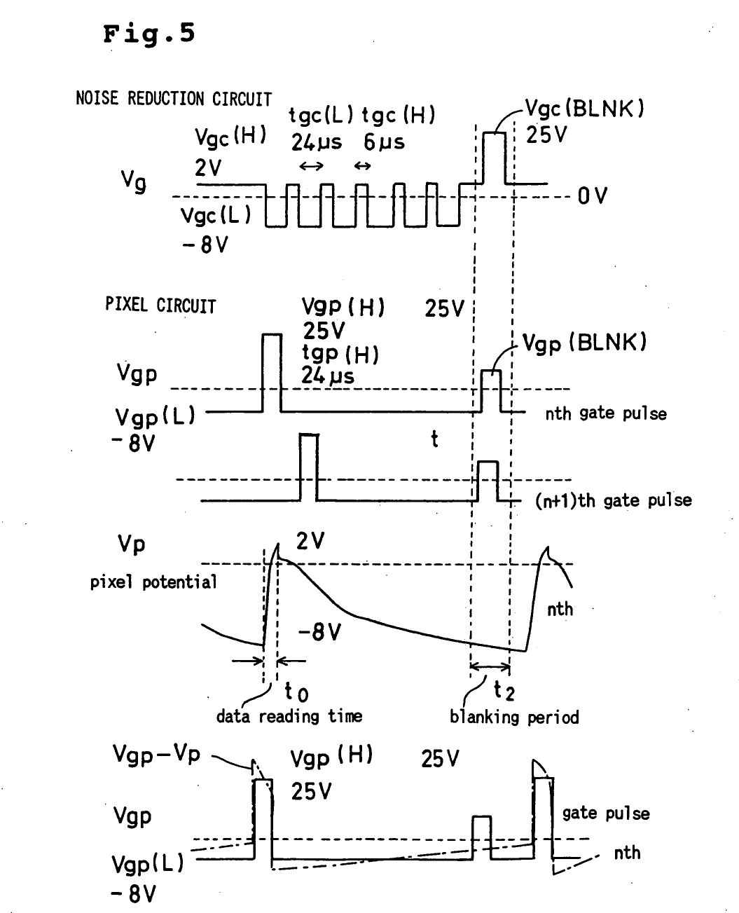

The present invention is also applicable to the noise corrective circuit. FIG. 5 shows pulse shapes of the gate voltage V_{gp} of the pixel circuit, pulse shapes of the gate voltage V_{g} applied to the noise corrective circuit, and the pixel voltage Vₚ. The pixel electrodes arranged in an array driven by the same image reading system as TV scanning whose unit is comprised of a horizontal scanning period, a vertical scanning period and a blanking period intervening between the two scanning periods mentioned above. The blanking period t₂ is set as a non-operating period when the X-ray radiation stops.

In order to cancel noise signals due to charging/discharging of stray capacitance caused by switching of the TFT in the conventional noise corrective circuit, a corrective pulse with the same amplitude as the gate voltage and the polarity opposite thereto is applied so as to generate noise signals by charging/discharging of the opposite polarity. In this case, it is necessary that the corrective pulse is controlled to be equal to or less than Vₜₕ of the TFT, because an error generates when the signal of the pixel electrode is read and varied by switch-on of the TFT owing to the corrective pulse. Therefore Vₜₕ-shift of the noise corrective circuit needs to be equal to or less than Vₜₕ. For conventional flat X-ray detectors, approximately −2.5 V of Vₜₕ-shift occurs after 50 thousand hour operation if V_{gc}(H) is 2 V and V_{gc}(L) is −2.5 V, so that the TFT becomes on-state when the corrective pulse is applied. Thus the correction is not exactly carried out. Accordingly it is necessary that V_{gc}(L) should be controlled to be small, that is equal to or smaller than −20 V preferably equal to or smaller than −10 V.

In FIG. 5, negative gate voltage pulse V_{gp}(L)(−8 V) for switch-off is applied to the gate electrode of the switching TFT and the TFT is switched off, except for the reading time t₀ for each pixel. Positive gate voltage pulse V_{gp}(H) (+25 V) for switch-on is applied thereto and the TFT is switched on for only 24 microseconds that is reading time. The figure shows the state in which the gate electrode of nth TFT is supplied with the gate voltage pulse V_{gp} for switch-on.

On the other hand, in the noise corrective circuit 34, a negative gate voltage pulse t_{gc}(L) having a polarity opposite to the voltage for a normal pixel is applied for 24 microseconds as the gate voltage V_{g} synchronizing with the data reading time t₀ from each signal output line so as to cancel a coupling electric charge with a parasitic capacitance. As a result, as shown by the V_{g} pulse form in FIG. 5, the noise corrective circuit is usually supplied with the positive normal gate voltage t_{gc}(H) for 6 microseconds, and negative pulses are applied thereto to the extent of the number of the signal lines per one frame. Correspondence between the gate pulse of the (n+1)th pixel switching TFT and the gate voltage pulse of the noise corrective circuit is shown for reference. In the case of this figure, a plurality (4 times) of noise corrective pixels per one signal line is applied to cancel the noise of an imaging pixel, and the gate voltage pulse (−8 V) of negative polarity being one to several times (about 4 times) of the normal gate voltage swing (+25−(−8)=33 V) of positive polarity is applied to the TFT of the corrective circuit. Though only one positive pulse per one frame is applied for the displaying pixels, multiple (the number of signal lines which is more than 1000) pulse of negative polarity is applied to the corrective circuit and the average bias over the whole period becomes effectively negative bias on average. Thus, by making the amplitude of the corrective pulse to be 1/(number of the corrective pixels), negative Vₜₕ-shift decreases and consequently problems due to the Vₜₕ-shift can be solved.

Furthermore, the problem of switch-on of the corrective pixel-switching TFT caused by the negative Vₜₕ-shift can be solved by decreasing the positive value V_{gc}(H) of the corrective voltage pulse according with the generation of Vₜₕ shift. This value of control V_{gc}(H) can be calculated by the equation (1).

Precisely, V_{gc}(H) changes from 2 V to −0.5 V, being decreased by about 2.5 V in 50 thousand hours. Besides, V_{gc}(H) is set to be lower than the maximum value of a negative shift of Vₜₕ, by setting V_{gc}(H) to be −0.5 V in advance.

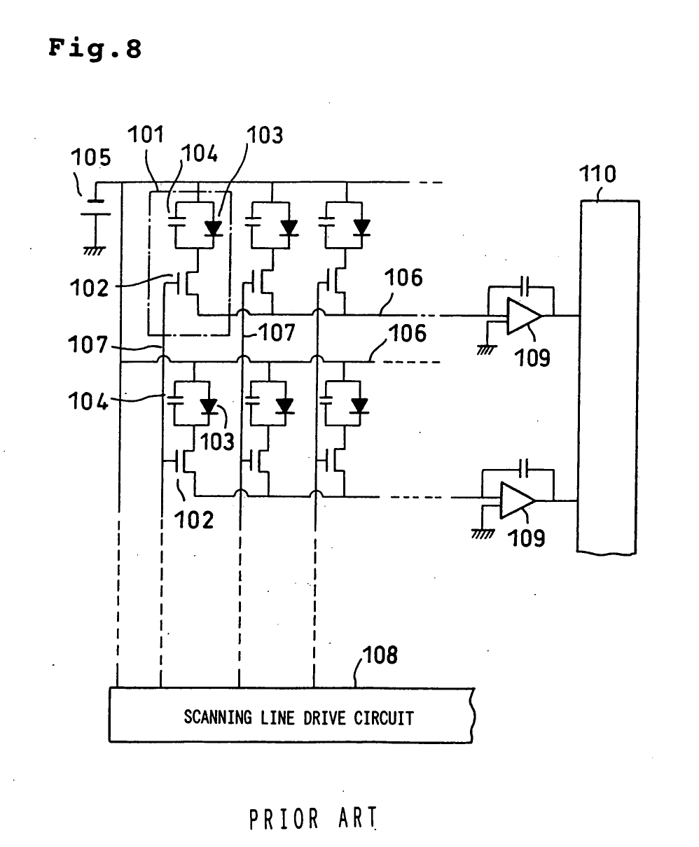

Next, a second embodiment that cancels Vₜₕ-Shift more easily will be explained. This can be realized by keeping an average supplying voltage for the noise corrective circuit and that for the pixel circuit having certain relation to each other. Usually it can be realized by sum of the total time for + (positive) bias being substantially equal to sum of the total time for − (negative) bias. Moreover, applying time for the negative bias can be more lengthened, because the shift due to negative bias is smaller than the shift due to positive bias as shown in FIG. 8.

That is to say, it is realized by satisfying the relation of following equation (2). The equation represents the sum of product of voltage and time of the applied pulse in one frame period. The average bias can be obtained by dividing this sum by the applied time of pulse:
V_{gp}(L)×(N_{sig}−1)×(t_{gp}(H)+t_{gp}(L))+V_{gp}(H)×1×t_{gp}(H)=(V_{gc}(H)×t_{c}(H)+V_{gc}(L)×t_{gc}(L) )×N_{sig} (2)
Marks are shown in FIG. 5. The letter p denotes the TFT of pixel circuit, and the letter c denotes the pulse to the TFT of corrective circuit. For example, if t_{gc}(H)=t_{gp}(H)=6 μs, V_{gc}(L)=−8V, V_{gc}(H)=2V, N_{sig}=1550, V_{gp}(H)=24V and V_{gp}(H)=−6V are given, the Vₜₕ-shift of the corrective circuit and that of the pixel circuit can be made the same to each other. In this case, V_{gc}(H)=2V, and V_{gc}(L)=−8V are preferable. The amplitude of the gate electrode of pixel circuit TFT is 24−(−6)=30V, and the amplitude of the corrective circuit is 2−(−8)=10V. Therefore noises caused by the capacitance of the pixel switching TFT can be canceled by correcting with 3 corrective TFTs, i.e., the charge generated by the capacitance of one TFT of imaging pixel with 30V amplitude is canceled with 3 TFTs in 3 corrective circuit pixels with 10V amplitude. By making the gate pulse of the corrective pixel satisfy substantially the equation (2) in compliance with the voltage and the pulse amplitude of the pixel circuit, the pixel circuit and the corrective circuit can coincide with each other in relation to the Vₜₕ-shift.

The equation (2) represents sum of the product of the voltage of applied voltage pulse and the applied time thereof in one frame period, and then the average applied voltage is obtained by the sum divided by one frame period. If the difference between the average applied voltage of the pixel switching TFT and that of other TFTs is within ±30% over a predetermined period, the difference between Vₜₕ-shift of the pixel switching TFT and that of other TFTs does not cause any problems practically on operation in the practical range. As shown in FIG. 5, effective gate voltage applied to the pixel TFT is V_{gp}−Vₚ and is not the same as V_{gp}. Therefore, though strict adjustment may be done, it does not matter practically as long as the average difference of applied voltages between the gate voltage of the corrective circuit TFT and the gate voltage of the pixel switching TFT is within ±30%.

Furthermore, it is practical that Vₜₕ-shift is reduced by applying a positive gate pulse (V_{gp}(BLNK)) to the pixel switching TFT during the blanking period t₂ that has no effect on the data reading, i.e. non-operating period as shown in the next embodiment. As the corrective pulse, a value that does not make the TFT be on-state, e.g. 1 volt is selected. Moreover, Vₜₕ is decreased by applying a positive gate voltage pulse (V_{gc}(BLNK)) (+25V) to the gate electrode of the TFT in the noise corrective circuit.

Therefore, the difference of Vₜₕ between the pixel circuit and the noise corrective circuit can be reduced than the case where the corrective pulse is not applied. The shift of Vₜₕ is represented by the equation (1).

In the the embodiment mentioned, corrective gate pulse was applied for both of pixel circuit and corrective circuit, it has meaningful effect, if corrective pulse was applied for either one of pixel circuit or the noise corrective circuit in the embodiment mentioned above.

Such effect can also be obtained for an indirect conversion type X-ray-electric conversion layer that converts an optical image generated by a fluorescent layer irradiated with X-ray, into an electric charge image through an photoconductive film.

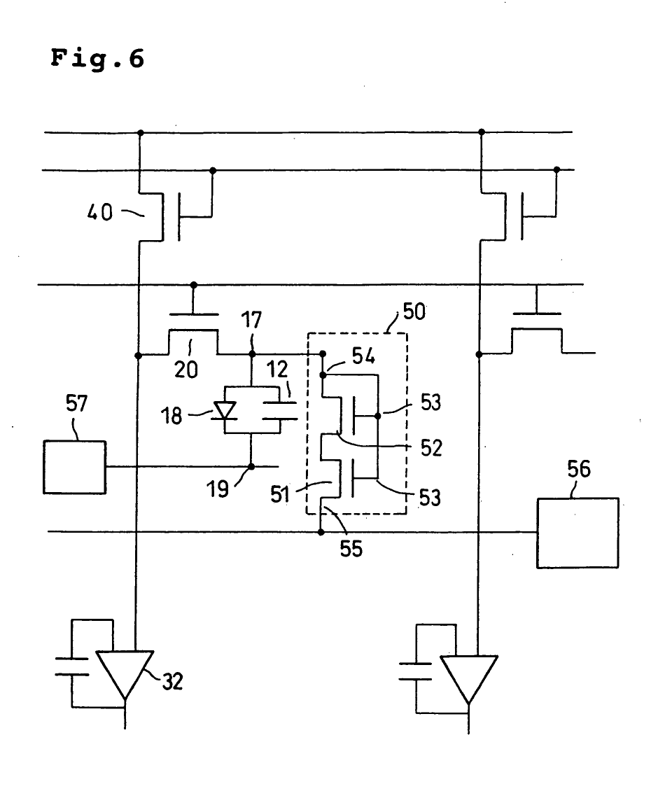

FIG. 6 shows the third embodiment of the present invention, in which a protection diode to prevent a breakdown of the TFT and the storage capacitor due to high voltage of the pixel potential is utilized, because a direct conversion type Se X-ray-electric conversion layer operates on the condition that a positive bias of +3 kV to +10 kV is applied thereto. The embodiment shows that it is capable to consider the same countercircuit to Vₜₕ-variation for such case. In this case, Se layers of p-type, i-type, and n-type on the pixel electrode are formed successively in this sequence.

The figure shows an equivalent circuit of the pixel connected to the protection diode of MISTFT. Each part with the same mark as used in FIGS. 1 to 4 is the same as that in these figures. The protection diode 50 is formed of a plurality of TFTs in series connection. In the figure, two TFTs 51, 52 constitute a series circuit. One end 54 of the circuit is connected to the pixel electrode 17, and the other end 55 thereof is connected to the protection diode power circuit 56. Both gate electrodes 53 of the TFTs 51, 52 are connected to each other, and furthermore to the pixel electrode 17.

For the direct conversion type, a high voltage of 3 to 10 kV is applied to the common electrode 19 of the X-ray-electric conversion layer through a bias power source 57. Therefore, because irradiation of intense X-ray raises the potential of the pixel electrode 17 and may cause a breakdown of the pixel switching TFT 20 or the storage capacitance 12, a maximum limited potential should be specified for the pixel electrode 17. The maximum limited potential can be specified by the bias potential of the protection diode 50 and is set to be approximately 10 to 30V. Thanks to the bias always supplied from the protection diode bias power source 56, a positive voltage that is the difference between the pixel potential and the protecting bias is always supplied to the protection diode TFT 50, and generates +shift of Vₜₕ, and then varies the threshold value of the protecting bias.

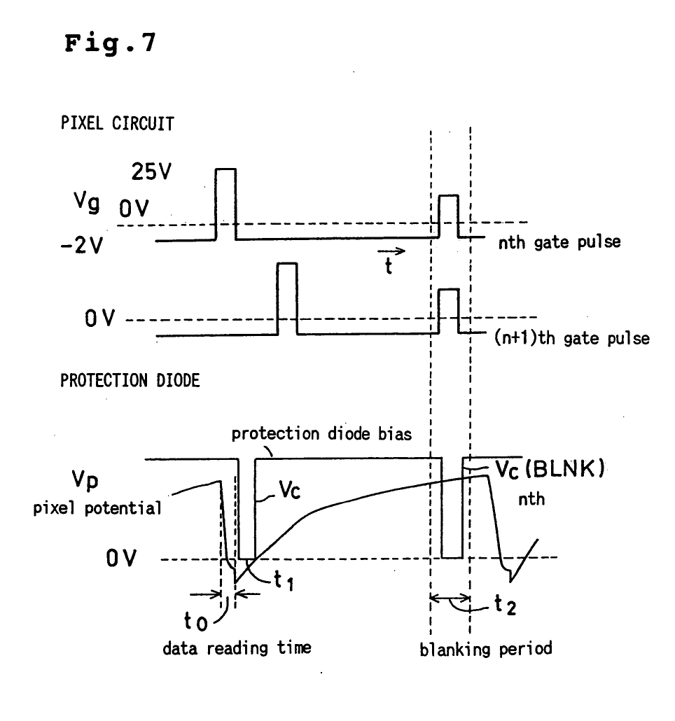

As shown in FIG. 7, applying corrective voltage pulses V_{c}, V_{c} (BLNK) in the range between the specified voltage and about 0 volt at the time t₁ that is immediately after reading the pixel potential or at the blanking period t₂ can prevent Vₜₕ from being increased. That is to say, applying a voltage having a polarity opposite to the average polarity of the voltage applied during operating period, at the time just after reading signals or at the blanking period when signal reading is not interfered can suppress Vₜₕ-shift. If the negative value of the voltage of this corrective voltage pulse exceeds Vₜₕ of the TFT, the protection diode is turned on, and then the signal charge of the pixel electrode 17 flows toward the power source circuit 56 for the protection diode. Therefore, the negative voltage should not be set to exceed Vₜₕ.

In the embodiment described above, explanation was carried out by the example which is comprised of an n-channel type TFT of a-Si, however a p-channel type can also be used in the same manner. The a-Si has an advantage that variation of the characteristics is small even if X-ray irradiates it. Furthermore, the same effect on the countercircuit for Vₜₕ-variation is expected for a TFT of poly-Si. Because the TFT can be made small by using poly-Si with higher mobility, effective area of the pixel becomes wide. Besides, as a peripheral circuit can be prepared on the same glass substrate, it has an advantage that manufacturing cost including the peripheral circuit can be reduced.

Though Vₜₕ-variation of the TFT depends slightly on the type and quality of the gate insulation film, passivation insulation film, etc., the value of the corrective pulse with opposite polarity, timing, etc. can be set to be the most appropriate value by designing in compliance with the property of Vₜₕ-variation of the TFT. The present invention is also available even if the form of the gate pulse of the pixel TFT or the noise corrective TFT is changed according to the purpose. A voltage pulse of a polarity opposite to the average bias at operating time may be applied thereto at non-operating period. Number of stages of the noise corrective circuit can suitably be changed in accordance with its purpose. It is sufficient that the amplitude of the gate voltage of pixel TFT is substantially equal to the product of the amplitude of the gate voltage of one corrective TFT and the number of stages. Applying a bias of a polarity opposite to that at normal operation when power is turned on but X-ray does not irradiate is also effective to a countercircuit for the Vₜₕ-variation.

The negative corrective pulse used in the present invention can be replaced by a constant voltage bias. For example, positive switch-on gate voltage pulse is usually applied to the TFT of the pixel circuit only at reading period, but the TFT is switched off being kept at certain Vₜₕ or lower during the other period. Therefore the constant voltage other than the voltage at switch-off period corresponds to the negative corrective voltage pulse of the present invention. Keeping the constant bias an appropriate value can prevent Vₜₕ from varying.

Consequently, variation of Vₜₕ can be suppressed by supplying a pulse with a polarity opposite to that at usual operating period to the potential between the gate and the source of TFT used in a pixel or a peripheral circuit of an X-ray imaging device in a medical X-ray diagnostic apparatus. Thus, variation of the characteristics of whole pick-up device can be diminished or made uniform, because variation of Vₜₕ of each TFT is kept to be substantially the same. Accordingly, usage of the apparatus with a lower intensity of X-ray, which is safe for the human body, can be accomplished.

1. An X-ray imaging device comprising:
an X-ray-electric conversion layer;
a plurality of pixel electrodes arranged in an array on one surface of the layer;
a field effect type thin film transistor connected to each pixel electrode for pixel switching, including source, drain and gate electrodes, either one of source and drain electrodes being connected to the pixel electrode, the other one being connected to a signal output line, and the gate electrode being connected to a scanning line; and
a gate drive circuit for switching the thin film transistor by applying a positive gate voltage pulse for switch-on to the gate electrode through the scanning line;
wherein the gate drive circuit in a switch-off period applies to the gate electrode a negative gate voltage for switch-off to prevent a threshold voltage from shifting generated by the positive gate voltage pulse for switch-on.

2. The X-ray imaging device as stated in claim 1, wherein the absolute value of the negative gate voltage for switch-off of the thin film transistor for pixel switching is 30 to 200% of the absolute value of the positive gate voltage pulse for switch-on.

3. The X-ray imaging device as stated in claim 1, wherein the device further comprises a noise corrective circuit comprising at least one stage of a field effect type thin film transistor connected to the signal output line in parallel, and the field effect type thin film transistor being supplied with a negative gate voltage for switch-off to prevent a threshold voltage from shifting caused by the positive gate voltage pulse for switch-on.

4. The X-ray imaging device as stated in claim 3, wherein the value at high voltage side of the gate voltage pulse for the field of effect type thin film transistor in the noise corrective circuit is reduced by the value of the threshold voltage-shift.

5. (canceled)

6. The X-ray imaging device as stated in claim 1, wherein the device further comprises:
a noise corrective circuit comprising field effect type thin film transistors connected to the signal output line in parallel, and
a correction control circuit for supplying a gate voltage pulse with a polarity opposite to the driver gate voltage pulse to the gate electrode of the thin film transistor in the noise corrective circuit while the pixel switching thin film transistor is operating,
and the correction control circuit supplies the gate electrode of the noise corrective circuit at non-operating period with a gate voltage pulse having a polarity of a direction that makes the mean polarity value of the gate voltage pulses be zero or reduced at operating period.

7. The X-ray imaging device as stated in claim 6, wherein the average supply voltage to the gate electrode of the thin film transistor in the noise corrective circuit is in the range between +30% and −30% of the average supply voltage to the pixel switching thin film transistor.

8. (canceled)

9. The X-ray imaging device as stated in claim 1, wherein the X-ray-electric conversion layer is comprised of a layer converting directly an X-ray image into an electric charge image, or of a layer converting an X-ray image into an optical image and then converting the converted optical image into an electric charge image.

10-11. (canceled)

12. The X-ray imaging device as stated in claim 6, wherein the thin film transistor for pixel switching and the thin film transistor in the noise corrective circuit are formed on the same substrate.

13. An X-ray imaging device comprising:
an X-ray-electric conversion layer,
a plurality of pixel electrodes arranged in an array on one surface of the layer,
a field effect type thin film transistor for pixel switching, one of whose source electrode and drain electrode is connected to the pixel electrode, the other thereof being connected to a signal output line, and whose gate electrode being connected to a scanning line,
a gate drive circuit switching the thin film transistor by supplying a gate voltage pulse to the gate electrode,
a noise corrective circuit comprising field effect type thin film transistors connected to the signal output line in parallel, and
a correction control circuit for supplying a gate voltage pulse having an opposite polarity to the driving gate voltage pulse to the gate electrode of the thin film transistor in the noise corrective circuit during operating period of the pixel switching thin film transistor,
wherein the correction control circuit supplies the gate electrode of the noise corrective circuit at non-operating period with a gate voltage pulse having a polarity of a direction that makes the mean polarity value of the gate voltage pulse be zero or reduced at operating period.

14. The X-ray imaging device as stated in claim 13, wherein the thin film transistors constituting the noise corrective circuit are arranged in a plurality of stages.

15. (canceled)
